(19) United States
(12) Patent Application Publication
(10) Pub. No.: US 2015/0271927 A1
(43) Pub. Date: Sep. 24, 2015

(54) INTEGRATED SOLDERING DEVICE

(71) Applicant: Tektronix, Inc., Beaverton, OR (US)

(72) Inventors: Thomas G. Cocklin, Portland, OR (US); Tony Lee Tarr, Portland, OR (US); Samuel M. Romey, Saint Paul, OR (US); Andy J. Heltborg, Aloha, OR (US); Jason Braunberger, Happy Valley, OR (US); Stephen G. Brown, Vancouver, WA (US); Glenn Klecker, Silverton, OR (US); Anthony Carcia, Portland, OR (US)

(21) Appl. No.: 14/607,300

(22) Filed: Jan. 28, 2015

Related U.S. Application Data
(60) Provisional application No. 61/954,842, filed on Mar. 18, 2014.

(51) Int. Cl. H05K 3/34; H01L 23/00; B23K 3/08; B23K 3/02; B23K 3/06

(52) U.S. Cl. CPC H05K 3/34; B23K 3/02; B23K 3/0615; B23K 3/063; B23K 3/0638; B23K 3/085; H01L 24/78; H01L 24/85

(57) ABSTRACT

An integrated soldering device comprising a wire feed mechanism, a heater configured to heat the wire, and an air recirculation system. The heated wire is fed from the device functions as the soldering tip as the device is used. The air recirculation system collects fumes and smoke generated by the soldering process.

### PRIORITY

This application claims benefit of U.S. Provisional Application No. 61/954,842, filed Mar. 18, 2014, which is hereby incorporated by reference in its entirety.

### BACKGROUND OF THE INVENTION

Often there is a need to test electronic equipment and components. To perform these tests, test leads are soldered, usually by hand, to pre-determined points to collect data. Depending on the complexity of the device or component, the number of test leads required may be few or many. There are other tasks, such as green-wire, re-soldering and de-soldering may also be done using this device.

As electronics and electronics packaging gets smaller and more complex, it is becoming more difficult and time consuming to wire test leads. The precision required for placement and the small field in which to operate makes it difficult for users using a traditional soldering iron and techniques to solder the test leads (or accomplish other tasks at this level). The users not only have to place and hold the wire and the soldering iron, but then solder the wire and hold the wire while it cures before cutting it to the proper length. This multi-step process is time consuming and taxing to the user.

There is a need for a new soldering device that integrates the many tools required for soldering, provides user flexibility for different soldering situations and assists the user with the task of soldering and placement.

### SUMMARY

An integrated soldering device and method for using the same is disclosed. The soldering device comprises mechanisms to assist a user with soldering tasks. A wire feeder dispenses the test lead (or in another instance a soldering tip) and a heater heats the wire to melt the solder to create the solder joint. An air handling system clears fumes and smoke away from the solder field to further assist the user. The consumables, solder paste and wire, may be stored in cartridges on the device, allowing for the easy replacement. The hand-held device may also include a light, a camera with magnification, a cutter, and/or a solder joint cooling system.

### BRIEF DESCRIPTION OF THE DRAWINGS

FIG. 1 illustrates a soldering device according to the some embodiments of the invention.

FIG. 2A illustrates the wire feed mechanism of the device of FIG. 1 in a first position.

FIG. 2B illustrates the wire feed mechanism of the device of FIG. 1 in a second position.

FIG. 2C illustrates the wire feed mechanism of the device of FIG. 1 in a third position.

FIG. 3A illustrates an embodiment of the wire heater of the device of FIG. 1.

FIG. 3B illustrates another embodiment of the wire heater of the device of FIG. 1.

FIG. 4A illustrates the air handling system of the device of FIG. 1.

FIG. 4B illustrates the air recirculation system of the device of FIG. 1.

FIG. 5 illustrates an embodiment of the camera and light systems of the device of FIG. 1.

FIG. 6A illustrates an embodiment of the solder dispenser of the device of FIG. 1.

FIG. 6B illustrates another embodiment of the solder dispenser of the device of FIG. 1.

FIG. 6C illustrates a further embodiment of the solder dispenser of the device of FIG. 1.

### DETAILED DESCRIPTION

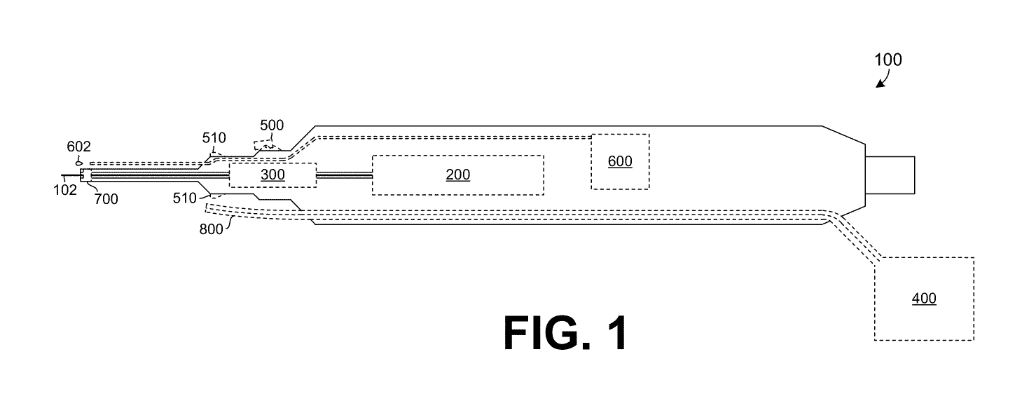

FIG. 1 illustrates a soldering device 100 that may include the following features: a wire feed mechanism 200 to advance the wire 102 through the device, a wire heater 300, an air handling system 400, a camera 500, lights 510, a solder dispensing system 600, a wire cutter 700, and a solder joint cooling system 800, each of which will be discussed in more detail below.

The soldering device 100 assists a user with soldering a wire 102 to a desired location (or soldering without the wire). The solder paste 602 may be dispensed from the device 100 by the solder dispensing system 600. However, the user may also manually provide solder paste to the wire 102 tip. The tip of the wire 102 is heated, by the wire heater 300, to act as a soldering iron. The hot wire 102 is then placed in the solder paste 602, melting the paste to create the solder joint. The hot joint is cooled and solidified by the cooling system 800. The desired length of wire 102 is dispensed from the device by the wire feed mechanism 200 and cut to length either manually or by the wire cutter 700.

An air handling system 400 evacuates fumes from the soldering joint to protect a user's health and a clear view of the soldering field.

The camera 500 and lights 510 assist the user with wire 102 placement. The camera 500 provides a magnified view to a display, allowing the user to more closely see the surface for soldering and thus assisting with greater accuracy in placing the wire 102 and soldering joint. The lights 510 may be used in conjunction with the camera 500, or alone, to light the field.

### Wire Feed Mechanism

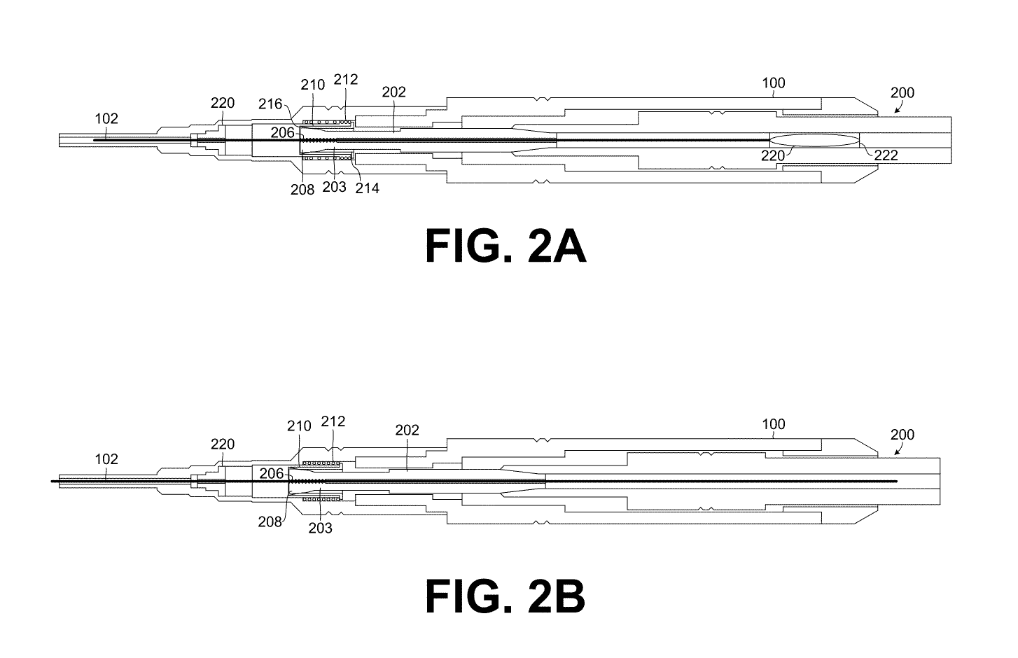

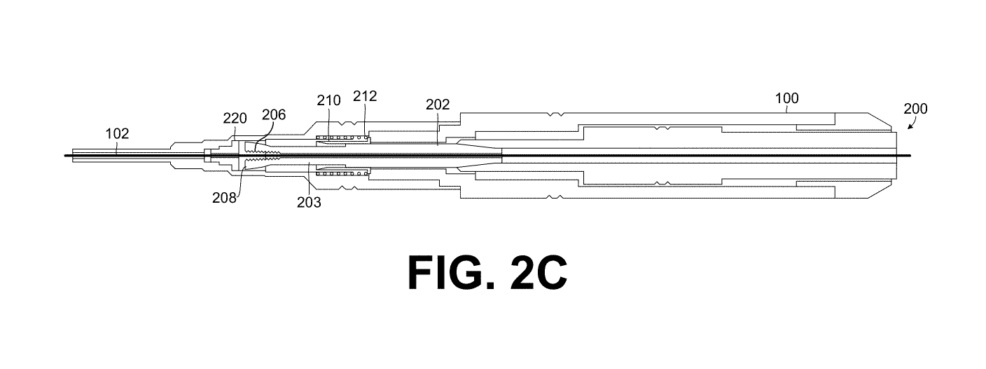

FIG. 2A shows the wire feed mechanism 200 used to advance the wire 102 from the device 100. The mechanism 200 may consist of a three-jaw chuck 202, a sleeve 210, a sleeve spring 212, and a rubber brake 220.

The three-jaw chuck 202 includes three jaws that extend from a central shaft. Each jaw 203 has teeth 206 on an interior side that grip the wire 102 and a flared protrusion 208 on an exterior side. Compression about the exterior circumference of the three jaws 203 of the chuck 202 causes the teeth 206 of each jaw 203 to engage or “pinch” the wire 102.

A rubber brake 220 is disposed inside the device 100 near the base of the double chuck mechanism 200. The brake 220 blocks the travel of the chuck 202 as it advances. Additionally, the brake 220 grips and retains the wire 102 using friction. The friction prevents the wire 102 from slipping through the mechanism 200 when the chuck 202 is not gripping the wire 102. The advancement of the chuck 202 exerts a force on the wire 102 that is sufficient to overcome the frictional force of the brake 220, allowing the wire 102 to advance from the device 100.

The sleeve 210 has a first diameter 214 and a second diameter 216, which is larger than the first diameter 214. The transition of the sleeve 210 from the first diameter 214 to the second diameter 216 follows the contour of the protrusion 208 of the three-jaw chuck 202. A sleeve spring 212 is disposed between the exterior of the sleeve 210 and the interior of the mechanism 200 housing.

In a first position of the mechanism, as shown in FIG. 2A, the sleeve and the three-jaw chuck 202 are engaged. The second diameter 216 of the sleeve 210 compresses the jaws 203 of the three-jaw chuck 202 about the wire 102. The compression of the jaws 203 about the wire 102 prevents the wire from traveling through the device. As the three-jaw chuck 202 and the sleeve 210 travel to a second position, or are “plunged,” the sleeve 210 and chuck 202 continue to be engaged and advance the wire 102. At the second position, as shown in FIG. 2B, the sleeve spring 212 is completely compressed preventing additional forward travel of the sleeve 210. At this position, the three-jaw chuck 202 continues to be driven forward. As the three-jaw chuck 202 travels forward past the sleeve 210, the protrusions 208 disengage from the second diameter 216 of the sleeve 210. The disengagement of the protrusions 208 causes the jaws 203 of the three-jaw chuck 202 to expand and the teeth 206 to disengage from the wire 102. At this point of disengagement, the advancement of the wire 102 is a negligible or zero amount. Free from the engagement with the protrusions 208, the sleeve 210 is driven back to a first position by the decompression of the sleeve spring 212.

The three-jaw chuck 202 continues to move forward until it reaches the limit of travel at a third position, as shown in FIG. 2C, at or near the brake 220. The driving force on the three-jaw chuck 202 disengages and the chuck 202 retracts back to the first position. As the jaws of the chuck return to the first position, the protrusions 208 engage with the sleeve 210. The engagement of the protrusions 208 and the sleeve 210 causes the jaws 203 to be compressed inward and grip the wire 102.

In an embodiment the three-jaw chuck 202 can be stopped at the third position allowing the wire 102 to be dispensed freely by pulling it from the mechanism 200.

The length of wire advanced with each cycle of the mechanism 200 is determined by the distance traveled by the sleeve between the first and the second positions. The distance traveled by the sleeve may be varied by the user by using a different length sleeve and spring set. This allows a user to select the length of wire advanced by each compression of the spring sleeve 210 and three-jaw chuck 202.

Alternatively, a stop, may be inserted between the spring 212 and the sleeve 210 (not shown). The stop shortens the travel length of the sleeve 210 between the first and second position, thus changing the length of the wire 102 dispensed.

In a further embodiment of the mechanism 200 (not shown), an external selector may be disposed that interfaces with the sleeve 210 interior of the mechanism. The selector allows the user to choose a desired wire 102 length to be dispensed. The movement of the selector may move a stop that prevents motion of the sleeve or alternatively the selector may shorten the distance of the spring by compressing it. Both options will shorten the distance the sleeve can travel between the first and second positions.

The movement of the sleeve 210 and the three-jaw chuck 202 may be actuated by a pneumatic or other suitable drive system. The actuation of the system can be controlled by a controller that triggers the advancement and retraction of the mechanism 200. The controller can be triggered to dispense the wire 102 automatically or manually by a user.

In the embodiment shown in FIG. 2A, the wire 102 is dispensed through the mechanism 200 from a spool 220. In some embodiments, the wire 102 is dispensed using a mechanical and/or electrical controller that feeds the wire. For example, the controller may include a mechanical or electrical pedal may be used to control the wire feed mechanism. As wire is advanced through the mechanism 200, it unwinds from the spool 220 which acts as a wire 102 reservoir. The spool is located in a cartridge 222 that is removable from the system allowing the user to insert a new cartridge 222 that has more wire 102 or wire having different properties. The ability to swap out different cartridges allows the user to change the wire easily and/or switch to a wire having different properties or composition for different tasks.

In an embodiment, the spool 220 may be created by axially winding the feed wire to create a center-pull spool 220. In this embodiment, there is no extraneous structure to the spool, the wire 102 itself forms the spool 220. The wire 102 is unwound from the spool 220 from the center, thus maintaining the structure of the spool 220 as the wire 102 is used.

The cartridge 222 and/or spool 220 may have a sensor or sensor system (not shown) that senses the amount of wire remaining on the spool 220. An indicator, such as an electronic LED or LCD indicator or a physical indicator or gauge, may interface with the sensor or sensor system and be used to display the condition and/or the amount of wire remaining on the spool 220. The sensor and display can display or indicate the amount of wire on the spool and/or provide an indication that the wire is about the run out.

Additionally, the mechanism 200 may feature a sensor or sensor system (not shown) that monitors the condition of the wire 102 as it passes through the device. The sensor or sensor system may be configured to monitor a number of wire conditions. Such conditions may include an “out-of-wire” or “out-of-alignment” condition. An “out-of-wire” condition may occur when the wire 102 has run out and/or is no longer capable of being advanced through the mechanism 200. An “out-of-alignment” condition may occur if the wire 102 miss-feeds through the device and is not engaged properly by the mechanism 200. The sensor or sensor system can communicate with the controller to control actuation of the mechanism 200 in a feedback configuration.

### Wire Heater

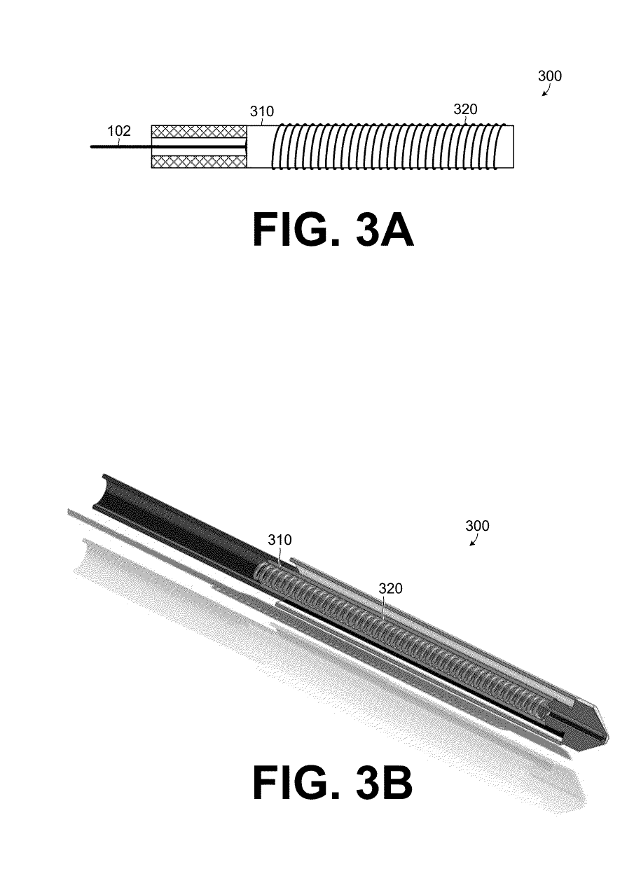

The wire heater 300, shown in FIG. 3A, heats the wire 102 as it is fed through the device 100. In the embodiment shown, the heater 300 includes a tube 310 and a heating element 320. The tube 310 is constructed of a thermally conductive material. The heating element 320 surrounds and heats the tube 310. In the embodiment shown, the heating element 320 may be a resistance wire that is wound around the tube 310. For example, the resistance wire may be a Nickel Chromium (Ni-Chrome) wire or any other type of that heats when current is applied to the wire. A power supply, not shown, energizes the Ni-Chrome wire heating element 320, causing the heating element to become hot. The thermal energy from the heating element 320 heats the tube 310. As the wire 102 advances through the tube 310, the wire 102 is heated to a sufficient temperature to be used in a soldering process. The wire 102, now heated, melts dispensed solder paste and solders the wire 102 to a user selected location.

The use of the wire 102 as a soldering tip for the device 100 ensures that the user is using a consistently new soldering tip. By soldering the exposed tip of the wire 102 to a desired location, and then advancing and trimming the wire to a desired length, a clean soldering tip is created.

In another embodiment, not shown, the tube 310 can have holes disposed about its length through which the heating element, Ni-Chrome wire, 320 passes through. Weaving the heating element through the tube 310 may heat the tube faster and more efficiently.

The energy flowing from the power supply into the heating element 320 can be adjusted by the user. Adjusting the power supply varies the temperature of the heating element 320. The Ni-Chrome wire used in the embodiment shown in FIG. 3 has thermal properties that correlate with the inputted energy. Therefore, by varying the power supply, the user can effectively set the temperature of the heating element 320 and the wire 102 as it is advanced through the heater 300. That is, the power supply provides enough energy to the heating element 320 to heat the wire 102 to a desired temperature that will melt the solder.

In yet another embodiment, shown in FIG. 3B, the heater 300 may include a pump that pumps air through the tube 310. Rather than only heating the wire 102, as discussed above, the heating element 320 heats the air pumped through the tube 310. The tube 310 can be profiled to concentrate and direct the flow of air exiting the tube 310. This allows the user to concentrate the flow of heated air to a specific point. The heated air melts the dispensed solder, allowing the wire 102 to be soldered or affixed to a desired location on a surface. As discussed above, the heating element 320 can be a Ni-Chrome wire, thus allowing the user to adjust the temperature of the heated air by varying the energy to the heating element 320, through a power supply.

Alternatively, the tube 310 may be a solid element having a tip that extends from the device 100 or a cartridge or tip can be inserted or affixed to the standard tube. Since a solid structure extends from the tube 310, the wire 102 cannot be fed through the device. In this embodiment, the device 100 effectively becomes a soldering iron, where the heating element 320 and tube 310 heat a tip that can be used to solder items or components as desired by the user. The use of the Ni-Chrome wire and variable power supply allows the user to control the temperature to which the soldering tip is heated.

### Air Handling System

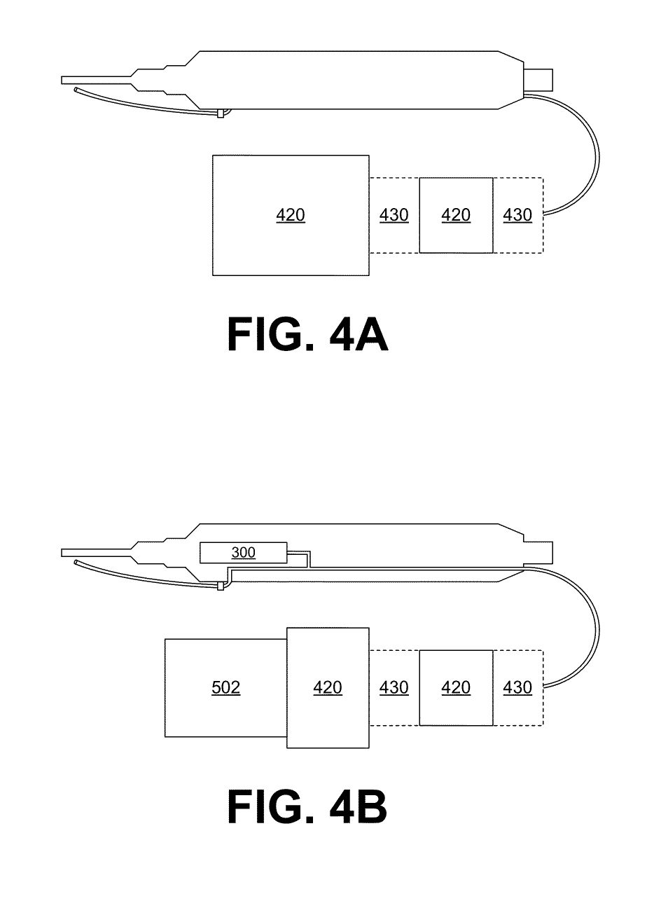

In some embodiments, the device 100 may include an air handling system 400, as shown in FIG. 4A. The air handling system 400 has an intake 402 located near the soldering tip of the device 100. A vacuum pump 410 is connected to the intake and is triggered by a controller 420 or a user. The vacuum pump 410 draws air through the intake 402 and away from the soldering point. Drawing fumes and smoke away from the soldering point protects the user's health and allows for greater site visibility. The air evacuated from the soldering point is passed through a filter 430 to trap any contaminants and pollutants. The contaminants and pollutants can be recovered from the filter for recycling or reuse. The cleaned air is then discharged into the surrounding environment.

### Air Recirculation System

In some embodiments, the air handling system 400 and the wire heater 300, of the device 100, may be integrated as shown in FIG. 4B. In the integrated form, the air removed from the solder point is filtered and then stored in a reservoir 440. Air is drawn from the reservoir 440 for use in the wire heater 300. The air drawn from the reservoir can be mixed with environmental air or gas sources depending on soldering needs and requirements. The air handling system 400 may be controlled by a controller that controls the vacuum of air, the mix of air and the introduction of air through the wire heater 300.

### Camera and Lights

A camera 500 may be mounted on the device 100, as shown in FIG. 1. Images from the camera 500 are transmitted to a display or virtual reality glasses for viewing. The camera 500 may be connected to the display through a wired or wireless connection. The camera 500 provides a magnified view of the work area to assist the user with placement of the wire and soldering accuracy. In the embodiment shown, the camera 500 is located near the soldering tip; alternatively, the camera may be placed anywhere on the device 100 and focused on the work field. The camera 500 has a resolution and field of view sufficient for a user performing the soldering task. In another embodiment, the camera may be removable, allowing for the device to be used absent the camera or use of an alternative camera. An alternative camera may have different properties that are more desirable by a user for certain tasks. Such properties can include the viewable wavelength, field of view and magnification. The camera feed may be sent to a monitor that is positioned so a user or operator's posture is in a neutral position and not bent over, such as when using a microscope.

A light system 510 may also be disposed on the device 100, as shown in FIG. 1. The light system 510 provides light for the camera 500 and illuminates the field for the user. In the embodiment shown in FIG. 1, the light system 510 comprises high discharge light-emitting diodes (LEDs) that are aimed at the same focal point as the camera 500. In an embodiment, the LEDs of the light system 510 can be adjustable by the user. Such adjustments can include the focal point of the light and intensity of light and the number and arrangement of the LEDs. In another embodiment, another suitable light source may be used in place of the LEDs; the replacement source should have similar compact overall package and sufficient light emission to illuminate the working field.

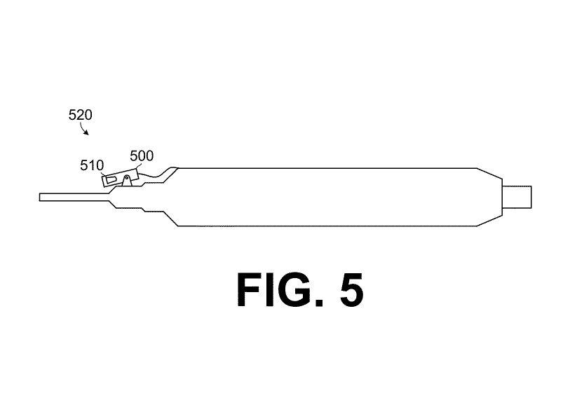

In another embodiment, the camera 500 and light system 510 may be integrated into a package 520, as shown in FIG. 5. The combined light and camera package 520 is mounted on the device 100 to illuminate the working field and relay images of the field to an external display viewable by a device user. An example of an integrated light and camera package 520 is a fiberscope. The fiberscope includes two optical fiber sets, a first set transmits light and a second set receives light. Light is transmitted from a source, external or mounted on the device, through the first set of optical fibers and illuminates the work field. The second set of optical fibers receives light reflected from the field; the reflected light is then displayed as an image for the user.

Images displayed from the camera system may also be recorded or captured for quality control or other purposes.

### Solder Dispenser

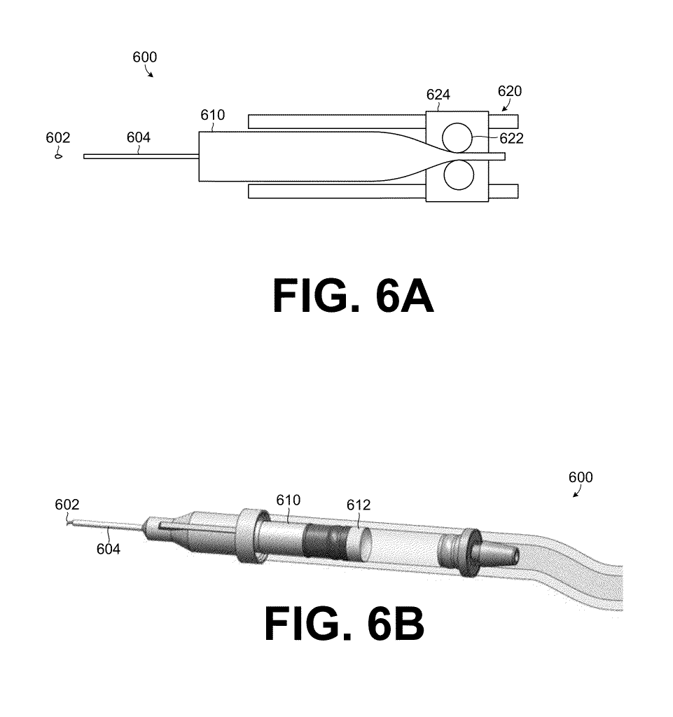

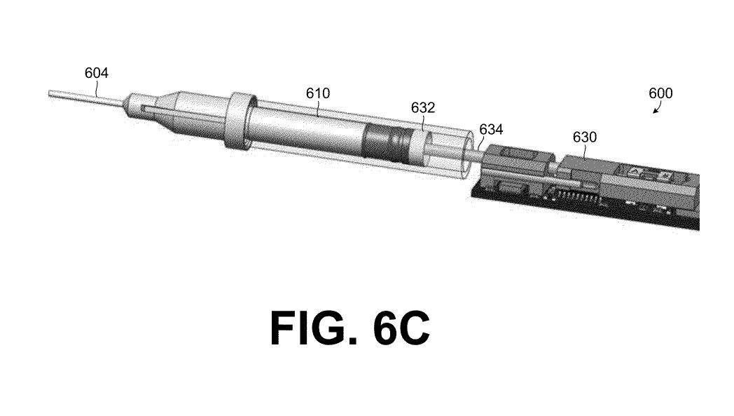

A solder dispensing system 600, shown in FIG. 6A, may be disposed on the device 100 of FIG. 1. However, as mentioned above, the user may also manually add solder paste to the tip of the wire 102 or to the surface the wire 102 is to be soldered on. The dispenser 600 dispenses a solder paste 602 at the point of soldering. In the embodiment shown, the solder dispensing system consists of a tube 610 containing solder paste 602, a dispensing mechanism 620 and an output 604. The solder paste 602 is contained in a tube 610 that is mounted into the system 600. The dispensing mechanism 620 consists of a pinch mechanism 622 and a twin-roller crawler 624. To dispense the paste 602, the pinch mechanism 622 squeezes the tube 610, forcing the solder paste 602 to be dispensed through the output 604. The twin-roller crawler 624 advances the pinch mechanism 622 along the length of the tube. Advancement of the pinch mechanism 622 along the tube length ensures that solder paste is consistently delivered from the output 604.

In an alternative embodiment, shown in FIG. 6B, the solder dispensing system 600 is a pneumatic powered dispenser. The solder paste 602 is contained in a tube 610 and a plunger 612 is disposed at an end of the tube. Pneumatic pressure on the plunger 612 causes the plunger to advance through the tube 610, forcing solder paste 602 through the output 604. The pneumatic pressure used to move the plunger 612 can come from a source external from the device. In an embodiment, the pneumatic pressure can be supplied from the air handling system.

In yet another embodiment, shown in FIG. 6C, the solder dispensing system 600 uses a linear motor 630. The linear motor 630 features a shaft 634 that is connected to a plunger 632. The plunger 632 interfaces with the solder paste tube 610 to force solder paste 602 through the output 604 as the plunger 632 is advanced by the shaft 634. The linear motor 630 can be a piezo-electric motor capable of incremented known extension lengths.

The amount of solder paste 602 dispensed through the output 604 may be controlled by a controller. The controller communicates with any of the embodiments discussed above to dispense a desired amount of solder paste. A user can control the amount of solder dispensed by dispensing a pre-set amount with each cycle or may have active control through the use of a button or other means. The active control allows the user to dispense any amount of solder as desired. Additionally, the system 600 and device 100 may include a sensor or sensor system (not shown) that provide feedback information to the controller to control the amount of solder paste dispensed. The sensor or sensor system may monitor such conditions as the amount of solder paste remaining, the amount of solder paste dispensed and the type and size of the wire 102, among others. The controller can process the sensor inputs to calculate a proper amount of solder paste to dispense and/or provide the user indications of the state of the solder paste, the amount of solder paste dispensed and the amount of solder paste to dispense.

In the embodiments described above, the solder paste 602 is contained in a tube 610 that may be removable and replaceable in the device 100. This allows the user to quickly and easily change the type of solder paste and to replace the tube 610 if the paste runs out.

### Wire Cutter

The device 100 of FIG. 1 may include a wire cutter 700, in some embodiments. The wire cutter 700 severs the wire 102 from the device 100. The wire cutter 700 is disposed near the soldering tip and severs the wire 102 on actuation by the user. The wire cutter 700 can be a mechanism suitable of severing the wire; such mechanisms include a user-actuated wire cutter, a pneumatically actuated wire cutter, and an electrically-actuated wire cutter.

### Solder Joint Cooling System

In some embodiments, a solder joint cooling system 800 may be disposed on the device 100, as shown in FIG. 1. The cooling system 800 features an outlet 802 located near the soldering end of the device 100. The cooling system 800 dispenses a forced air blast that assists in setting the solder. Air used in the system 800 may be compressed environmental air, air from the air handling reservoir, or other sources. A user actuates a release mechanism that causes a blast of compressed air to be dispensed through the outlet 802. The rush of air across the hot solder cools and solidifies the solder.

Having described and illustrated the principles of the disclosed technology in a preferred embodiment thereof, it should be apparent that the disclosed technology can be modified in arrangement and detail without departing from such principles. We claim all modifications and variations coming within the spirit and scope of the following claims.

1. A hand-held soldering device, comprising:
a wire feeder configured to advance a wire to a tip of the soldering device; and
a heater configured to heat the wire as a soldering tip to attach the wire to a surface with solder during a soldering process.

2. The soldering device of claim 1 in which
the heater includes:
a tube,
a heating element in direct contact with the tube, and
a power supply connected to the heating element; and
the wire feeder is further configured to advance the wire to the tip of the soldering device through the tube.

3. The soldering device of claim 2 in which the heating element is a nickel chromium wire.

4. The soldering device of claim 2 in which the tube comprises a thermally conductive material.

5. The soldering device of claim 1, further comprising an air recirculation system configured to collect air generated during the soldering process.

6. The soldering device of claim 5 in which the air recirculation system includes:
a filter,
a bladder, and
a vacuum configured to draw air from the tip of the soldering device through the filter into the bladder during the soldering process.

7. The soldering device of claim 1 in which the wire feeder includes a cartridge containing a spool of wire.

8. The soldering device of claim 7 in which the wire feeder includes:
a wire feed drive system connected to the cartridge containing the spool of wire, and
a controller configured to operate the wire feed drive system.

9. The soldering device of claim 8 in which the controller is a mechanical controller.

10. The soldering device of claim 8 in which the wire feed drive system includes a pneumatically driven plunger and pinch mechanism.

11. The soldering device of claim 7 in which the soldering device includes an indicator configured to indicate when the cartridge is empty.

12. The soldering device of claim 7 in which the wire feeder further includes a sensor configured to sense an out-of-wire condition, and the controller is further configured to be deactivated in response to the sensed out-of-wire condition.

13. The soldering device of claim 7 in which the cartridge containing a spool of wire is removable.

14. The soldering device of claim 1 further comprising a solder paste dispenser.

15. The soldering device of claim 14 in which the solder paste dispenser includes:
a cartridge containing solder,
a solder paste feed system connected to the cartridge containing solder and configured to dispense solder from the cartridge containing solder, and
a controller configured to operate the solder paste feed system.

16. The soldering device of claim 15 in which the solder paste feed system is further configured to dispense solder to a point of soldering.

17. The soldering device of claim 15 in which the solder paste feed system comprises a piston configured to displace solder paste within the cartridge containing solder to output solder to the tip of the wire.

18. The soldering device of claim 17 in which the piston is pneumatically driven.

19. The soldering device of claim 17 in which the piston is electrically driven.

20. The soldering device of claim 17 in which the cartridge containing the solder paste is removable.

21. The soldering device of claim 1 further comprising a camera.

22. The soldering device of claim 1 further comprising an illumination device.

23. The soldering device of claim 1 further comprising a cutter configured to cut the wire after the wire has been attached to the surface during the soldering process.

24. The soldering device of claim 1 further comprising a cooling system configured to output cool air to solidify the wire and the solder to the surface.

25. A hand-held soldering device, comprising:
a wire feeder configured to advance a wire to a tip of the soldering device;
a heater configured to heat the wire as a soldering tip to attach the wire to a surface with solder during a soldering process;
an air recirculation system configured to collect air generated during the soldering process;
a cooling system configured to output cool air to solidify the wire and the solder to the surface;
a camera; and
an illumination device.

26. A soldering device, comprising:
a wire feeder configured to advance a wire to a tip of the soldering device;
a heater configured to heat the wire as a soldering tip to attach the wire to a surface with solder during a soldering process;
an air recirculation system configured to collect air generated during the soldering process;
a camera located at a distal end of the soldering device; and
an illumination device located at the distal end of the solder device.

27. A method for soldering a wire to a surface with a hand-held soldering device, comprising:
feeding wire to a tip of the hand-held soldering device;
heating the wire to a desired temperature;
supplying solder to a soldering location; and
soldering the wire with the solder to the surface when the wire is heated to the desired temperature and the solder is supplied to the soldering location.
